(19) United States
(12) Patent Application Publication
(10) Pub. No.: US 2005/0084990 A1
(43) Pub. Date: Apr. 21, 2005

(54) Endpoint detection in manufacturing semiconductor device

(76) Inventors: Yuh-Turng Liu, Hsinchu (TW); Kuang-Chao Chen, Hsinchu (TW); Hsueh-Hao Shih, Hsinchu (TW); Yun-Chi Yang, Hsinchu (TW); Yung-Tai Hung, Hsinchu (TW)

Correspondence Address: Yitai Hu;SHAW PITTMAN LLP, 1650 Tysons Boulevard, McLean, VA, 22102, US

(21) Appl. No.: 10/685,484

(22) Filed: Oct. 16, 2003

(51) Int. Cl. H01L 21/66; G01R 31/26; H01L 21/44; H01L 21/4763; H01L 21/302; H01L 21/461

(52) U.S. Cl. 438/16; 438/633; 438/692

(57) ABSTRACT

A method of manufacturing a semiconductor device that comprises the steps of providing a semiconductor wafer including a patterned layer, forming a first insulating layer over the patterned layer of the semiconductor wafer, the first insulating layer including a first index of refraction, forming a second insulating layer over the first insulating layer, the second insulating layer including a second index of refraction smaller than the first index of refraction, removing the second insulating layer by a planarizing process, and detecting a change in index of refraction during the planarizing process.

### DESCRIPTION OF THE INVENTION

1. Field of the Invention

This invention relates in general to semiconductor device manufacturing and, more particularly, to a polish stop layer in a semiconductor layer for optical detection.

2. Background of the Invention

In the semiconductor industry, it is generally required to form various material layers or structures over previously formed layers and structures in manufacturing semiconductor devices. However, the prior formations may leave the top surface topography of an in-process wafer highly irregular, for example, with bumps, trenches or other surface irregularities. These surface irregularities of the prior layers often cause problems to subsequent layers, resulting in poor yield and device performance. Accordingly, it is generally necessary to have a flat and planar surface through wafer planarization.

A planarization method in the art for removing surface irregularities is chemical mechanical polishing (“CMP”). A CMP process may involve rotating a semiconductor wafer with respect to a polishing pad with slurry serving as a polishing agent between the wafer and the pad. A silicon oxide layer may be formed over the semiconductor wafer to protect a patterned layer previously formed on a HENDERSON surface of the wafer during the CMP process. The silicon oxide layer may include a thickness of approximately 10K to 20K angstroms (A), which will then be polished to a thickness of approximately 5K to 10K A.

One problem with the CMP process is the proper determination of a planarization endpoint. In general, it is necessary to determine whether a wafer has been planarized to a desired flatness or thickness by detecting the surface characteristics of the wafer. Since it is not possible to perform the detection during a CMP process, one conventional method requires an operator to remove a control wafer from the CMP process, examine the control wafer for a desired endpoint, and load a production wafer into the CMP process. This conventional method of endpoint detection is labor-intensive and time-consuming.

Another problem with the CMP process is the unequal elevation between a central portion and an edge portion of a polished wafer due to different rotation speeds between the central and edge portions of a polishing pad. The unequal elevation may lead to poor yield and device performance.

Therefore, there is a general need in the art for a method to provide a more accurate determination of an endpoint in wafer planarization, and a more efficient way of detecting the endpoint for the CMP process.

### SUMMARY OF THE INVENTION

Accordingly, the present invention is directed to a method that obviates one or more of the problems due to limitations and disadvantages of the related art.

To achieve these and other advantages, and in accordance with the purpose of the invention as embodied and broadly described, there is provided a method of manufacturing a semiconductor device that comprises the steps of providing a semiconductor wafer including a patterned layer, forming a first insulating layer over the patterned layer of the semiconductor wafer, the first insulating layer including a first index of refraction, forming a second insulating layer over the first insulating layer, the second insulating layer including a second index of refraction smaller than the first index of refraction, removing the second insulating layer by a planarizing process, and detecting a change in index of refraction during the planarizing process.

In one aspect, the method further comprises the step of ceasing the planarizing process when the change in index of refraction is detected.

In another aspect, the method further comprises the step of removing a portion of the first insulating layer by the planarizing process when the change in index of refraction is detected.

Also in accordance with the present invention, there is provided a method of endpoint detection for a chemical mechanical polishing (CMP) process in manufacturing a semiconductor device, the method comprising the steps of patterning a semiconductor wafer, forming a first insulating layer over the patterned semiconductor wafer, the first insulating layer including a first index of refraction, forming a second insulating layer over the first insulating layer, the second insulating layer including a second index of refraction smaller than the first index of refraction, removing the second insulating layer by the CMP process, detecting a change in index of refraction during the CMP process, and determining an endpoint for the CMP process.

Still in accordance with the present invention, there is provided a method of endpoint detection for a chemical mechanical polishing (CMP) process in manufacturing a semiconductor device, the method comprising the steps of providing a semiconductor wafer including a patterned layer, forming an insulating layer conformally with the patterned layer, the insulating layer including a first removal rate and a first index of refraction, forming a silicon oxide layer over the first insulating layer, the silicon oxide layer including a second removal rate greater than the first removal rate, and a second index of refraction smaller than the first index of refraction, removing the silicon oxide layer by the CMP process, detecting a change in index of refraction during the CMP process, and ceasing the CMP process when the change in index or refraction is detected.

Further still in accordance with the present invention, there is provided a semiconductor device that comprises a semiconductor wafer having a patterned layer, a first insulating layer over the patterned layer, the first insulating layer having a first index of refraction, and a second insulating layer over the first insulating layer, the second insulating layer having a second index of refraction smaller than the first index of refraction, wherein the second insulating layer is removed by a planarization process when a change in index of refraction is detected.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIGS. 1A to 1C are schematic diagrams illustrating the manufacturing of a semiconductor device in accordance with one embodiment of the present invention; and

FIG. 2 is a graphical diagram illustrating a simulation result of a method in accordance with one embodiment of the present invention.

### DESCRIPTION OF THE EMBODIMENTS

Reference will now be made in detail to the present embodiment of the invention, an example of which is illustrated in the accompanying drawings. Wherever possible, the same reference numbers will be used throughout the drawings to refer to the same or like parts.

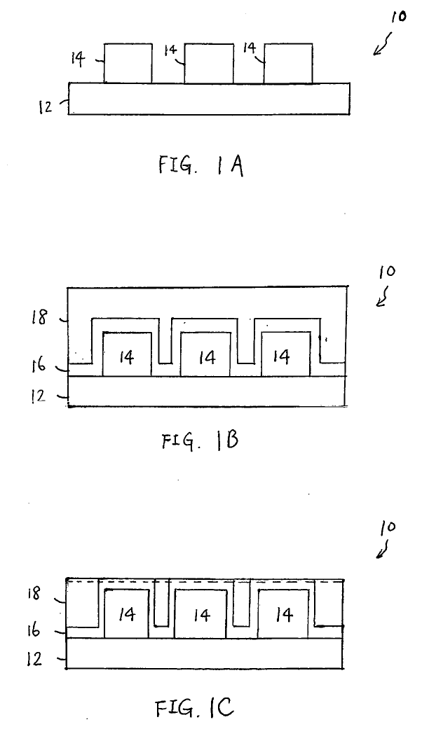

FIGS. 1A to 1C are schematic diagrams illustrating the manufacturing of a semiconductor device 10 in accordance with one embodiment of the present invention. Referring to FIG. 1A, semiconductor device 10 includes a substrate 12 and a patterned layer 14. Substrate 12 may include various material layers or structures (not shown) depending on the desired functions of semiconductor device 10. Patterned layer 14 is formed over substrate 12, and generally includes a conductive layer comprised of polysilicon or metal such as aluminum or copper.

Referring to FIG. 1B, prior to planarization by a planarizing process, a first insulating layer 16 is formed over patterned layer 14, and then a second insulating layer 18 is formed over first insulating layer 16. In one embodiment according to the present invention, first insulating layer 16 is formed conformally with patterned layer 14 by chemical vapor deposition (“CVD”). As will be described in following paragraphs, first insulating layer 16 functions to serve as a polish stop layer for the CMP process. First insulating layer 16 includes a first removal rate and a first index of refraction. In one embodiment according to the present invention, the first removal rate is smaller than approximately 1000 Å per minute, and the first index of refraction is approximately 2. In another embodiment, first index of refraction is greater than 2. First insulating layer 16 may include silicon nitride (SiN), silicon oxide nitride (SiON) or silicon rich oxide (“SRO”) of a thickness ranging from 500 to 2000 Å.

Second insulating layer 18 has a second removal rate greater than the first removal rate of first insulating layer 16, and a second index of refraction smaller than the first index of refraction of first insulating layer 16. In one embodiment according to the present invention, the second removal rate is approximately three times the first removal rate, or 3000 Å per minute, and the second index of refraction is 1.4 and 1.5. Second insulating layer 18 may include silicon oxide of a thickness ranging from 10K to 20K Å.

In another embodiment according to the invention, an oxide layer (not shown) is formed over patterned layer 14 before first insulating layer 16 is formed. The oxide layer functions to provide a planarized surface for first insulating layer 16.

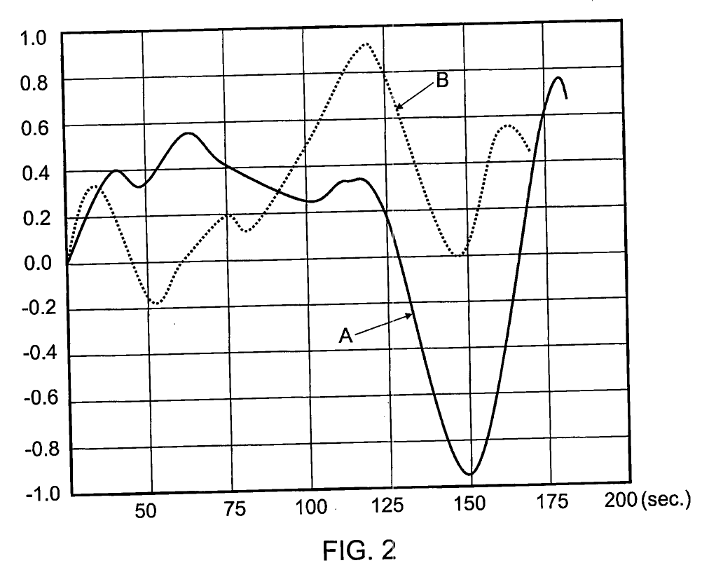

Referring to FIG. 1C, second insulating layer 18 is removed by performing a planarizing process, for example, a chemical mechanical polishing (“CMP”) process to expose first insulating layer 16. In one embodiment according to the present invention, the CMP process is performed to expose a portion of first insulating layer 16, as shown with the dotted line in FIG. 1C. With a smaller removal rate than that of second insulating layer 18, it will be more difficult to polish away first insulating layer 16, which can be used as a polish stop for the CMP process. First insulating layer 16 can further alleviate the problem of unequal elevation between a central portion and edge portions of semiconductor device 10 after polishing. Moreover, with a greater index of refraction than that of second insulating layer 18, first insulating layer 16 can be used to determine an endpoint for the CMP process, as exemplarily described below with respect to FIG. 2.

FIG. 2 is a diagram showing a simulation result of a method in accordance with one embodiment of the present invention. Referring to FIG. 2, curve A is an optical endpoint curve for a first semiconductor wafer being planarized by CMP for a first time period. Curve B is an optical endpoint curve for a second semiconductor wafer being planarized by CMP for a second time period shorter than the first time period. The first and second semiconductor wafers have the same material layers and structures, including a silicon nitride (SiN) layer and a silicon oxide (SiO₂) layer formed over the SiN layer. When a semiconductor wafer simply includes the SiN and SiO₂ layers without any underlying material layers or structures, the optical endpoint curve of that semiconductor wafer will behave like a sinusoidal wave.

The simulation result shown in FIG. 2 is provided by a monitor (not shown) that includes a light source for radiating a laser beam toward a semiconductor wafer under a CMP process, and a detector for detecting the strength of a laser beam reflected from the semiconductor wafer. The horizontal and vertical axes of FIG. 2 respectively represent the CMP processing time and the strength of a reflected laser beam. In one embodiment according to the present invention, the monitor is an in-situ removal monitor (“ISRM”) mounted on a CMP polisher.

FIG. 2 reveals a significant fall in the strength of the reflected laser beam in curves A and B. The fall results from a change in index of refraction, as will be described below. In general, the amplitude of the fall increases as the index of refraction increases, or as the CMP processing time increases. Since the first semiconductor wafer endures a longer CMP processing time than the second semiconductor wafer, the amplitude of the fall in curve A is greater than that in curve B. At the time point of approximately 120 seconds, the significant fall in the reflected light strength begins to occur because the SiO₂ layer is removed to an extent that exposes the SiN layer having a greater index of refraction than that of the SiO₂ layer. This time point, where a change in index of refraction occurs, can be used as an endpoint for the CMP process. To determine a CMP endpoint, a software program associated with the ISRM is generally employed to calculate the slope of curve A or B. The software program determines an endpoint for a CMP process where a continuous declining slope below a predetermined slope value is located.

The present invention also provides a method of endpoint detection for a CMP process in manufacturing a semiconductor device. The method begins with providing a patterned semiconductor wafer. A first insulating layer having a first index of refraction is then formed over the patterned semiconductor wafer. A second insulating layer is formed over the first insulating layer. The second insulating layer includes a second index of refraction smaller than the first index of refraction of the first insulating layer. The second insulating layer is removed by a CMP process. Next, a change in index of refraction during the CMP process is detected by a monitor. The monitor indicates an endpoint for the CMP process if the change in index of refraction is detected. The monitor subsequently sends a signal regarding the information of the endpoint to control software. The control software then ceases the operation of CMP devices in response to the signal sent from the monitor.

The second insulating material formed at the edge portions is generally polished away quicker than the material formed at the central portions of a wafer. As a result, an endpoint can be determined prior to the total removal of the second insulating material formed at the central portions. In one embodiment according to the present invention, a portion, for example, 10% of thickness, of the first insulating layer is polished away by the CMP process to ensure complete planarization.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method of manufacturing a semiconductor device comprising the steps of:
providing a semiconductor wafer including a patterned layer;
forming a first insulating layer over the patterned layer of the semiconductor wafer, the first insulating layer including a first index of refraction;
forming a second insulating layer over the first insulating layer, the second insulating layer including a second index of refraction smaller than the first index of refraction;
removing the second insulating layer by a planarizing process; and
detecting a change in index of refraction during the planarizing process.

2. The method of claim 1 further comprising the step of ceasing the planarizing process when the change in index of refraction is detected.

3. The method of claim 1 further comprising the step of removing a portion of the first insulating layer by the planarizing process when the change in index of refraction is detected.

4. The method of claim 1 further comprising the step of forming the first insulating layer conformally with the patterned layer.

5. The method of claim 1 further comprising the step of forming the first insulating layer with one of silicon nitride, silicon oxide nitride and silicon rich oxide.

6. The method of claim 1 further comprising the step of forming the second insulating layer with silicon oxide.

7. The method of claim 1 further comprising the step of providing the first insulating layer with a first removal rate, and the second insulating layer with a second removal rate greater than the first removal rate.

8. The method of claim 1 wherein a chemical mechanical polishing process is used as the planarizing process.

9. The method of claim 1 wherein the first index of refraction is approximately equal to or greater than 2.

10. The method of claim 1 wherein the second index of refraction is approximately equal to or smaller than 1.5.

11. The method of claim 1 further comprising the step of forming an oxide layer over the patterned layer of the semiconductor wafer before forming the first insulating layer.

12. A method of endpoint detection for a chemical mechanical polishing (CMP) process in manufacturing a semiconductor device, comprising the steps of:
patterning a semiconductor wafer;
forming a first insulating layer over the patterned semiconductor wafer, the first insulating layer including a first index of refraction;
forming a second insulating layer over the first insulating layer, the second insulating layer including a second index of refraction smaller than the first index of refraction;
removing the second insulating layer by the CMP process;
detecting a change in index of refraction during the CMP process; and
determining an endpoint for the CMP process.

13. The method of claim 12 further comprising the step of removing a portion of the first insulating layer by the CMP process when the endpoint is determined.

14. The method of claim 12 further comprising the step of forming the first insulating layer with one of silicon nitride, silicon oxide nitride and silicon rich oxide.

15. The method of claim 12 further comprising the step of providing the first insulating layer with a first removal rate, and the second insulating layer with a second removal rate greater than the first removal rate.

16. The method of claim 15, the second removal rate being approximately three times the first removal rate.

17. A method of endpoint detection for a chemical mechanical polishing (CMP) process in manufacturing a semiconductor device, comprising the steps of:
providing a semiconductor wafer including a patterned layer;
forming an insulating layer conformally with the patterned layer, the insulating layer including a first removal rate and a first index of refraction;
forming a silicon oxide layer over the first insulating layer, the silicon oxide layer including a second removal rate greater than the first removal rate, and a second index of refraction smaller than the first index of refraction;
removing the silicon oxide layer by the CMP process;
detecting a change in index of refraction during the CMP process; and
ceasing the CMP process when the change in index or refraction is detected.

18. The method of claim 17 further comprising the step of removing a portion of the insulating layer when the change in index of refraction is detected.

19. The method of claim 17 further comprising the step of providing a monitor in detecting the change in index of refraction.

20. A semiconductor device comprising:
a semiconductor wafer having a patterned layer;
a first insulating layer over the patterned layer, the first insulating layer having a first index of refraction; and
a second insulating layer over the first insulating layer, the second insulating layer having a second index of refraction smaller than the first index of refraction,
wherein the second insulating layer is removed by a planarization process when a change in index of refraction is detected.

21. The device of claim 20 wherein the planarization process is ceased when the change in index of refraction is detected.

22. The device of claim 20 wherein the first insulating layer is formed conformally with the patterned layer.

23. The device of claim 20, the first insulating layer further comprising one of silicon nitride, silicon oxide nitride and silicon rich oxide.

24. The device of claim 20, the second insulating layer further comprising silicon oxide.

25. The device of claim 20, the first insulating layer further comprising a first removal rate, and the second insulating layer further comprising a second removal rate greater than the first removal rate.

26. The device of claim 20 wherein the planarization process is a chemical mechanical polishing (CMP) process.

27. The device of claim 20, the second removal rate being approximately three times the first removal rate.
